(19) United States
(12) Patent Application Publication
(10) Pub. No.: US 2026/0305409 A1
(43) Pub. Date: Oct. 1, 2026

(54) METHODS OF SINGULATING EMBEDDED INTERCONNECT BRIDGE DIE STRUCTURES

(71) Applicant: Intel Corporation, Santa Clara, CA (US)

(72) Inventors: Bhaskar Jyoti Krishnatreya, Beaverton, OR (US); Brad Hamlin, Portland, OR (US); Julia Chiu, Portland, OR (US); Kevin Lee, Beaverton, OR (US); Anil Kumar Chandolu, Boise, ID (US); Md Shahriar Khandaker, Hillsboro, OR (US); Ravindranadh Tagore Eluri, Tempe, AZ (US); Kamran Keramatnejad, Portland, OR (US)

(73) Assignee: Intel Corporation, Santa Clara, CA (US)

(21) Appl. No.: 19/094,420

(22) Filed: Mar. 28, 2025

(51) Int. Cl. H01L 23/538; H01L 21/48; H01L 23/00; H01L 25/11

(52) U.S. Cl. CPC H10W 70/65; H10W 70/05; H10W 70/611; H10W 70/635; H10W 90/00; H10W 72/248; H10W 72/252; H10W 90/724

(57) ABSTRACT

Microelectronic integrated circuit package structures include a package structure comprising an embedded bridge interconnect structure within a substrate, the embedded interconnect bridge structure having a plurality of vias extending through a silicon layer, the silicon layer having two or more scallop structures. A non-conductive layer is on a first side of the silicon layer, and a dielectric layer is on a second side of the silicon layer. A plurality of die contacts are at least partially on a surface of the dielectric layer. A first die is over the embedded interconnect bridge structure, the first die coupled to the plurality of die contacts. A second die is over the embedded interconnect bridge structure, adjacent to the first die, the second die coupled to the plurality of die contacts.

### BACKGROUND

In electronics manufacturing, integrated circuit (IC) packaging is a stage of manufacture where an IC that has been fabricated on a die or chip comprising a semiconducting material is coupled to a supporting case or “package” that can protect the IC from physical damage and support electrical interconnect suitable for further connecting to a host component, such as a printed circuit board (PCB). In the IC industry, the process of fabricating a package is often referred to as packaging, or assembly.

As semiconductor IC packaging architectures continue towards more complex and more compact systems, embedded interconnect bridge structures (EMIB) may be employed to provide high density interconnect capabilities for heterogenous dies on a single package. A typical EMIB includes a small bridge chip embedded in a package substrate which enables very high density die-to die connections in fine line and spacing traces, for example. However, singulation of EMIB structures can result in front side and back side chipping failure modes and thus reduces yield.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1A is a cross-sectional view of an EMIB-T bridge structure, in accordance with some embodiments.

FIG. 1B is a cross-sectional view of a side profile of a silicon portion of the EMIB bridge structure of FIG. 1A, in accordance with some embodiments.

FIG. 1C is a cross-sectional view of an EMIB-T bridge structure, in accordance with some embodiments.

FIG. 1D is a cross-sectional view of an EMIB bridge structure, in accordance with some embodiments.

FIGS. 2A-2E are cross-sectional views of methods of forming EMIB-T bridge structures, in accordance with some embodiments.

FIGS. 3A-3E are cross-sectional views of methods of forming EMIB-T bridge structures, in accordance with some embodiments.

FIGS. 4A-4H are cross-sectional views of methods of forming EMIB-T bridge structures, in accordance with some embodiments.

FIGS. 5A-5E are cross-sectional views of methods of forming EMIB-T bridge structures, in accordance with some embodiments.

FIGS. 6A-6F are cross-sectional views of methods of forming EMIB bridge structures, in accordance with some embodiments.

FIGS. 7A-7G are cross-sectional views of methods of forming EMIB bridge structures, in accordance with some embodiments.

FIG. 8 is a cross-sectional view of an IC package structure comprising glass core units, in accordance with some embodiments.

FIG. 9 illustrates a flow chart of processes for the fabrication of IC package structures having EMIB bridge structures, in accordance with some embodiments.

FIG. 10 is a functional block diagram of an electronic computing device, in accordance with some embodiments of the present disclosure.

### DETAILED DESCRIPTION

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause and effect relationship).

The terms “over,” “under,” “between,” and “on” as used herein refer to a relative position of one component or material with respect to other components or materials where such physical relationships are noteworthy. For example in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the explicit context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent.

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

The term “dielectric” generally refers to any number of non-electrically conductive materials that make up the structure of a package substrate.

The term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and carries the same meaning.

The term “solder bump” generally refers to a solder layer formed on a bond pad. The solder layer typically has a round shape, hence the term “solder bump”.

The term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

Views labeled “cross-sectional”, “profile” and “plan” correspond to orthogonal planes within a Cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Embodiments discussed herein address problems associated with singulating EMIB structures for incorporation into packaging architectures. Stealth dicing or saw blade dicing of EMIB structures can result in front side and back side chipping failure modes. These chipping failures reduce die break strength and can act as nucleation points for die crack during die attach to a substrate resulting in poor yield at substrate assembly processes. Embodiments described herein include utilizing dry etch processing for both EMIB comprising through silicon vias (TSVs) and EMIB structures without TSV's. The embodiments herein eliminate the chipping and reduced die break strength failure modes.

The embodiments described herein enable a higher yield and greater reliability of package structures including singulated EMIB structures fabricated according to the various embodiments. The embodiments herein include methods of processing IC glass panels which enable ultra large form factor (ULFF) artificial intelligence (AI) high performance computing (HPC) packaging architectures.

The architectures described herein may be assembled and/or fabricated with one or more of the features or attributes provided in accordance with various embodiments. A number of different assembly and/or fabrication methods may be practiced to enable the formation of singulated EMIB package structures which prevent stress related fractures during processing, according to one or more of the features or attributes described herein.

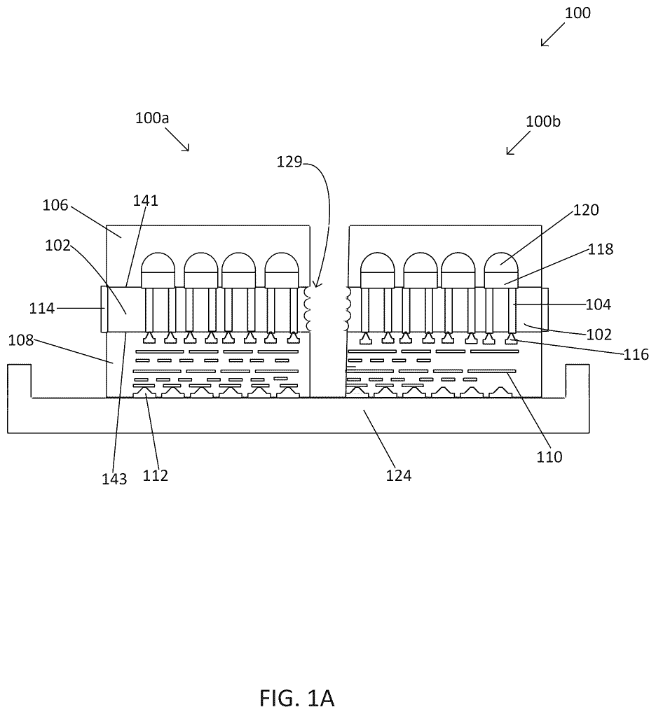

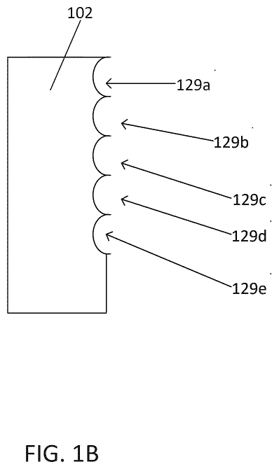

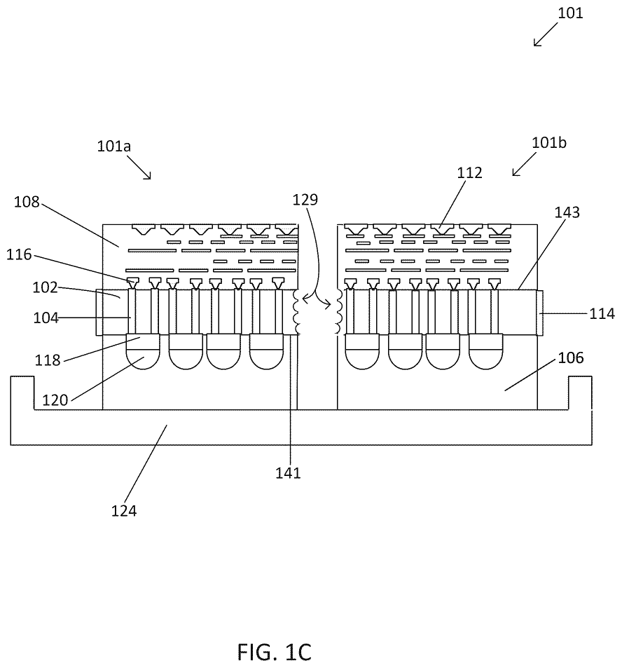

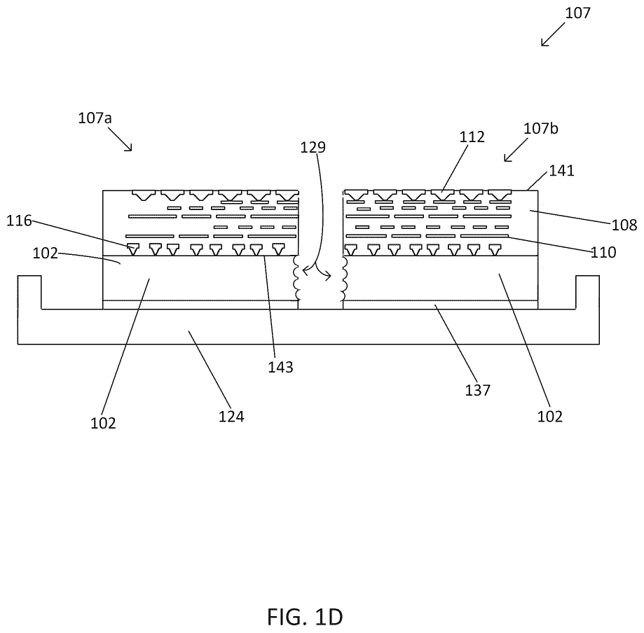

FIGS. 1A-1D illustrate embodiments of singulated EMIB structures which utilize dry etch singulation processing which eliminates chipping and reduced die break strength failure modes and hence eliminates risks of poor yields at bridge assembly processes. The package structures may be formed utilizing standard IC processing techniques. The methods of fabrication described herein create improved device performance in advanced 2.5D and 3D packaging.

FIG. 1A is a cross-sectional view of a portion of an embedded multi die interconnect bridge (EMIB) structure 100 subsequent to a singulation process. In an embodiment, the EMIB structure 100 depicts two EMIB structures 100a, 100b. In an embodiment, each of the EMIB structures 100a, 100b comprise a silicon material 102 having a first side 141 and a second side 143. The silicon material 102 may comprise dimensions of 0.5 mm×0.5 mm, in an embodiment, and an aspect ratio of 3 mm×36 mm in an embodiment. An edge portion of the silicon material 102 may comprise one or more scallop structures 129, which may be formed due to a singulation process to be described subsequently herein. In an embodiment, the one or more scallop structures may comprise one or more semicircular indentations within a sidewall of the silicon material. In an embodiment, a silicon nitride material 114 is on a sidewall of the silicon material 102, opposite a sidewall of the silicon material 102 comprising the one or more scallops 129.

One or more through silicon vias (TSVs) 104 may extend from the first side 141 and the second side 143 of the silicon material 102. The one or more TSVs 104 may be filled with a conductive material such as copper or copper alloys, in an embodiment. The one or more TSVs may can be used to provide conductive paths between the EMIB structure 100 and other devices, such as a PC board or an IC die.

A non-conductive layer 106 may be on the first side 141 of the silicon material 102. In an embodiment, the non-conductive layer 106 may comprise an adhesive material comprising a resin, a filler, a curing agent and/or a solvent. In an embodiment, the non-conductive film 106 may comprise a thickness above a solder cap 120 of about 3 to 5 microns and may be applied to reduce chips and cracks during singulation processes, such as during dicing process, for example. In an embodiment, the solder cap 120 may comprise one or more of silicon, gold, or tin, or may comprise any other suitable solder materials as are known in the art. The solder cap 120 may be on a pillar structure 118, which may comprise copper or copper alloys in an embodiment.

A dielectric material 108 may be on the second side of the silicon material 102. In an embodiment, the dielectric material 108 may be formed from an epoxy based resin such as bisphenol A, epoxy resin, a bisphenol F epoxy resin, a novolac epoxy resin, an aliphatic epoxy resin, a glycidylamine epoxy resin, and a glycidylamine epoxy resin, or any other resin including one or more terminal epoxy groups. The dielectric material 108 may comprise an organic laminate material, in an embodiment. Conductive traces 110 may be distributed throughout the dielectric layer 108 to connect devices, such as IC die or a board, such as a printed circuit (PC) board, for example, with the EMIB structure 100.

In an embodiment, the conductive traces 110 may comprise any suitable conductive material such as copper or its alloys. Conductive TSV contacts 116 within/on a surface of the dielectric material 108 may be electrically and physically coupled with the one or more TSVs 104 within the silicon material 102. Conductive die contacts 112 may be within/on a surface of the dielectric material 108 and may be on a surface of a carrier structure 124, which may comprise a mylar carrier structure 124 in an embodiment. Conductive die contacts may comprise electrically conductive pads which may include conductive metal, such as copper, gold, silver, aluminum, zinc, nickel, brass, bronze, iron, etc.

FIG. 1B is a cross-sectional view of a silicon material 102 sidewall portion depicting the one or more scallops 129 of FIG. 1A. While FIG. 1B depicts scallops 129a-129e, the number of scallops 129 and the spacing between individual scallops such as the scallops 129a-129e may vary depending upon the singulation process, which may include a silicon plasma dry etching process for example. In an embodiment, the scallops 129a-129e may comprise one or more semicircular indentations.

FIG. 1C depicts a cross-sectional view of a portion of an EMIB structure 101 subsequent to a singulation process. In an embodiment, the EMIB structure 101 depicts two EMIB structures 101a, 101b. In an embodiment, each of the EMIB structures 101a, 101b comprise a silicon material 102 having a first side 141 and a second side 143. The silicon material 102 may comprise dimensions of 0.5 mm×0.5 mm, in an embodiment, and an aspect ratio of 3 mm×36 mm in an embodiment. An edge portion of the silicon material 102 may comprise one or more scallop structures 129, which may be formed due to a singulation process to be described subsequently herein. In an embodiment, a silicon nitride material 114 is on a sidewall of the silicon material 102, opposite a sidewall of the silicon material 102 comprising the one or more scallops 129.

One or more TSVs 104 may extend from the first side 141 and the second side 143 of the silicon material 102. The one or more TSVs 104 may be filled with a conductive material such as copper or copper alloys, in an embodiment.

A non-conductive layer 106 may be on the first side 141 of the silicon material 102. In an embodiment, the non-conductive layer 106 may comprise an adhesive material comprising a resin, a filler, a curing agent and/or a solvent. In an embodiment, the non-conductive film 106 may comprise a thickness above a solder cap 120 of about 3 to 5 microns. The solder cap 120 may be on a pillar structure 118, which may comprise copper or copper alloys in an embodiment. A surface of the non-conductive material 106 may be on a surface of a carrier structure 124, which may comprise a mylar carrier structure 124 in an embodiment.

A dielectric material 108 may be on the second side 143 of the silicon material 102. In an embodiment, the dielectric material 108. Conductive traces 110 may be distributed throughout the dielectric layer 108 to connect devices, such as IC die or a board, such as a printed circuit (PC) board, for example, with the EMIB structure 101.

In an embodiment, the conductive traces 110 may comprise any suitable conductive material such as copper or its alloys. Conductive TSV contacts 116 within/on a surface of the dielectric material 108 may be electrically and physically coupled with the one or more TSVs 104 within the silicon material 102. Conductive die contacts 112 may be within/on a surface of the dielectric material 108.

FIG. 1D depicts cross-sectional views of an EMIB structure 107 subsequent to a singulation process. In an embodiment, the EMIB structure 107 depicts two EMIB structures 107a, 107b. In an embodiment, each of the EMIB structures 107a, 107b comprise a silicon material 102 having a first side 141 and a second side 143. The silicon material 102 may comprise dimensions of 0.5 mm×0.5 mm, in an embodiment, and an aspect ratio of 3 mm×36 mm in an embodiment. An edge portion of the silicon material 102 may comprise one or more scallop structures 129, which may be formed due to a singulation process to be described subsequently herein. The second side 143 of the silicon material 102 may be on a surface of a film 13, such as a die attach film (DAF) film. The (DAF) film may be on a surface of a carrier structure 124, which may comprise a mylar carrier structure 124 in an embodiment.

A dielectric material 108 may be on the second side 143 of the silicon material 102. Conductive traces 110 may be distributed throughout the dielectric layer 108 to connect devices, such as IC die or a board, such as a printed circuit (PC) board, for example, with the EMIB structure 101.

In an embodiment, the conductive traces 110 may comprise any suitable conductive material such as copper or its alloys. Conductive contacts 116 within/on a surface of the dielectric material 108 may be electrically and physically coupled with the silicon material 102. Conductive die contacts 112 may be within/on a surface of the dielectric material 108.

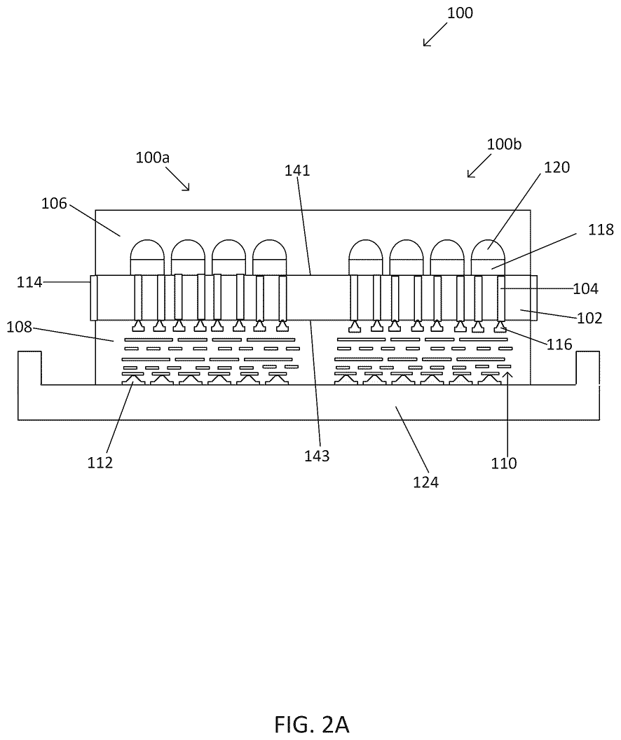

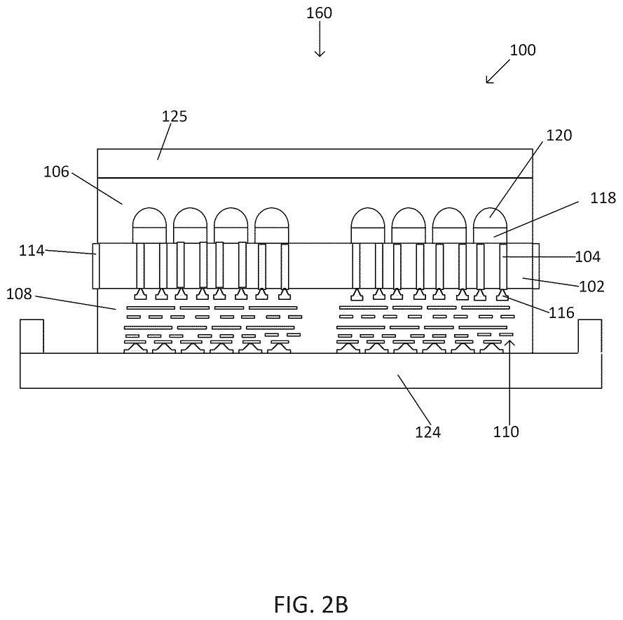

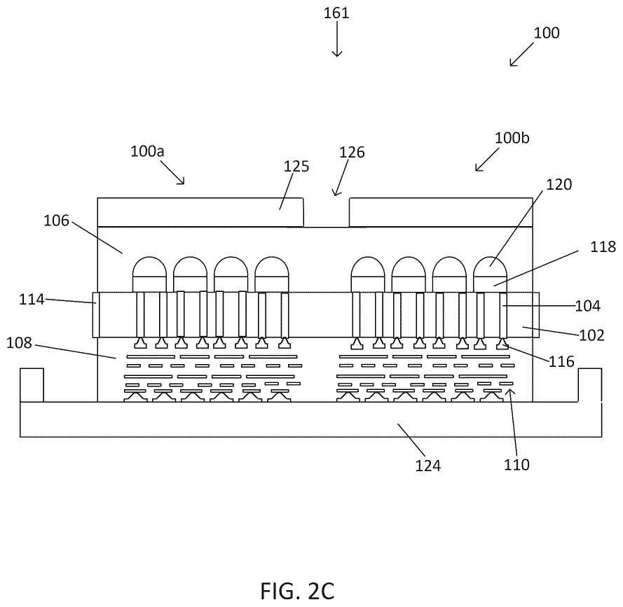

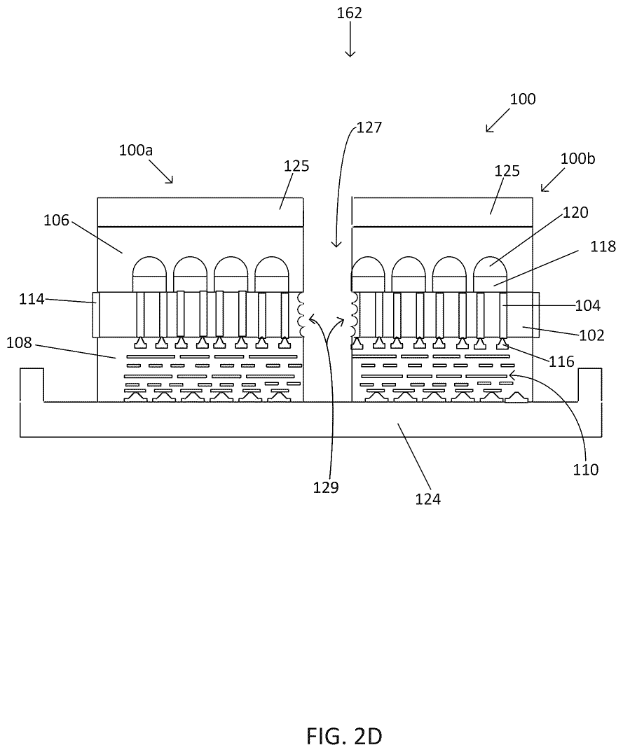

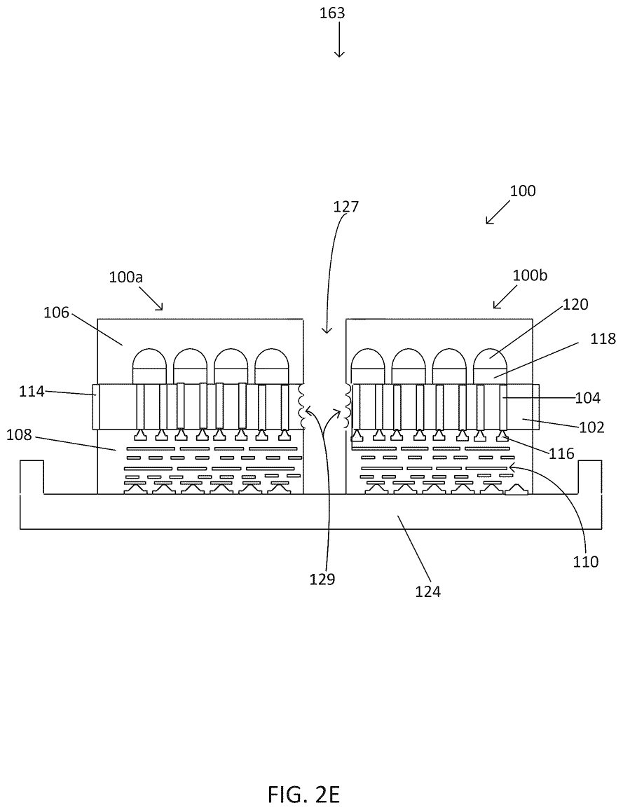

FIGS. 2A-2E depict methods of forming and singulating EMIB structures having TSVs according to embodiments, such as those depicted in FIGS. 1A-1C for example. FIG. 2A depicts a cross-sectional view of a portion of an EMIB structure 100 prior to a singulation process. EMIB structure 100 comprises two EMIB structures-a first EMIB structure 100a and a second EMIB structure 100b to be singulated from each other in a subsequent dry etching process. In an embodiment, each of the EMIB structures 100a, 100b comprise a silicon material 102 having a first side 141 and a second side 143. The silicon material 102 may comprise any suitable dimensions. In an embodiment, the dimensions of the silicon material 102 may comprise about 0.5 mm×0.5 mm and an aspect ratio of about 3 mm×36 mm. In an embodiment, a silicon nitride material 114 is on a sidewall of the silicon material 102.

One or more TSVs 104 may extend between and through the first side 141 and the second side 143 of the silicon material 102. The one or more TSVs 104 may be filled with a conductive material such as copper or copper alloys, in an embodiment. A non-conductive layer 106 may be on the first side 141 of the silicon material 102. In an embodiment, the non-conductive layer 106 may comprise an adhesive material comprising a resin, a filler, a curing agent and/or a solvent. In an embodiment, the non-conductive film 106 may comprise a thickness above a solder cap 120 of about 3 to 5 microns. In an embodiment, the non-conductive film 106 may comprise a laminate film 106. In an embodiment, the solder cap 120 may comprise one or more of silicon, gold, or tin, or may comprise any other suitable solder materials as are known in the art. The solder cap 120 may be on a pillar structure 118, which may comprise copper or copper alloys in an embodiment.

A dielectric material 108 may be on the second side of the silicon material 102, with conductive traces 110 distributed throughout the dielectric layer 108 to connect devices, such as IC die or a board, such as a printed circuit (PC) board, for example, with the EMIB structure 100. In an embodiment, the conductive traces 110 may comprise any suitable conductive material such as copper or its alloys. Conductive TSV contacts 116 within/on a surface of the dielectric material 108 may be electrically and physically coupled with the one or more TSVs 104 within the silicon material 102. Conductive die contacts 112 may be within/on a surface of the dielectric material 108 and may be on a surface of a carrier structure 124, which may comprise a mylar carrier structure 124 in an embodiment.

FIG. 2B depicts a process 160 wherein a coating layer 125 may be formed on a top surface of the non-conductive layer 106. In an embodiment the coating layer 125 may comprise a resist material, and the process 160 may comprise a wafer coating process, wherein the coating layer 125 may be sprayed onto the surface of the non-conductive layer 106. FIG. 2C depicts a patterning process 161 wherein an opening 126 between the first EMIB structure 100a and the second EMIB structure 100b is formed. In an embodiment, the patterning process 161 may comprise a laser patterning process 161. In an embodiment, the laser patterning process 161 may utilize a femto second laser scribe.

FIG. 2D depicts a process 162 wherein a removal process 162 is employed wherein the non-conductive material 106 is patterned using a femto second laser scribe for example, followed by a dry etch process to etch the silicon material 102, and then etching the dielectric material 108 to singulate the first EMIB structure 100a from the second EMIB structure 100b. In an embodiment, the dry silicon etch process portion of the multi-step removal process 162 may comprise a silicon dry etch, such as a Botsch etch process, or may comprise any suitable plasma etch process, for example. In an embodiment, the removal process 162 may first form an opening 127 through the non-conductive film 106, then through the silicon material 102 and then through the dielectric material 108. The removal process 162 stops on the carrier structure 124. The opening 127 singulates the first EMIB structure 100a from the second EMIB structure 100b.

In an embodiment, the silicon etch portion of the removal process 162 forms scallop structures 129 on an edge/sidewall portion of the silicon material 102. In an embodiment, the silicon nitride material 114 is on a sidewall of the silicon material 102 that is opposite a sidewall of the silicon material 102 comprising the one or more scallops 129. Sidewalls of the non-conductive material 106 and sidewalls of the dielectric material 108 are free of the scallop structures 129. A plasma dicing process may be employed in an embodiment. FIG. 2E depicts a process 163, such as an ashing process with a wet cleaning process for example, of the first and second EMIB structures 100a, 100b. In an embodiment, the non-conductive layer 106, the silicon material 102 and the dielectric material may be etched to form the opening 127 within one process tool, using up to 3 different chambers.

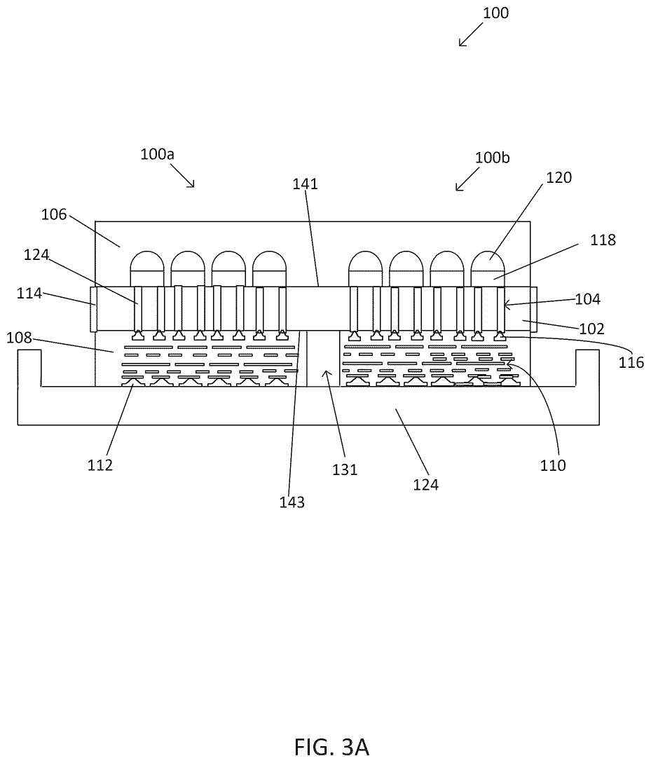

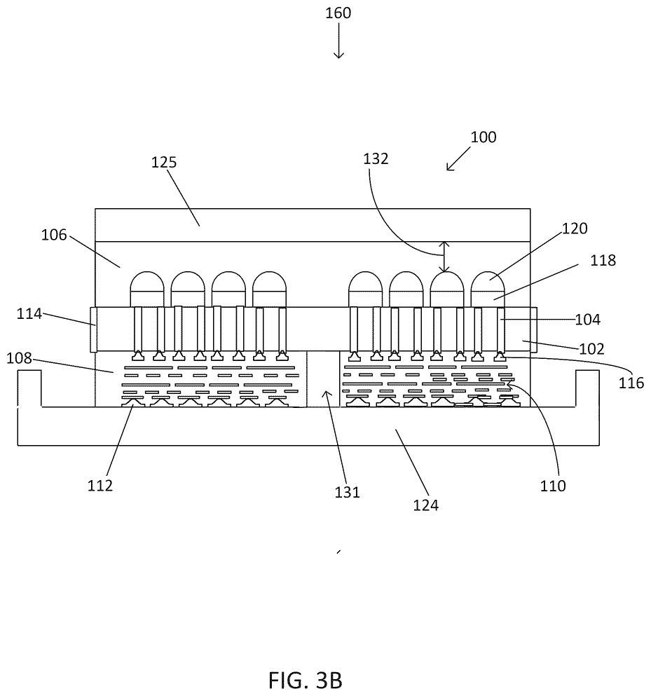

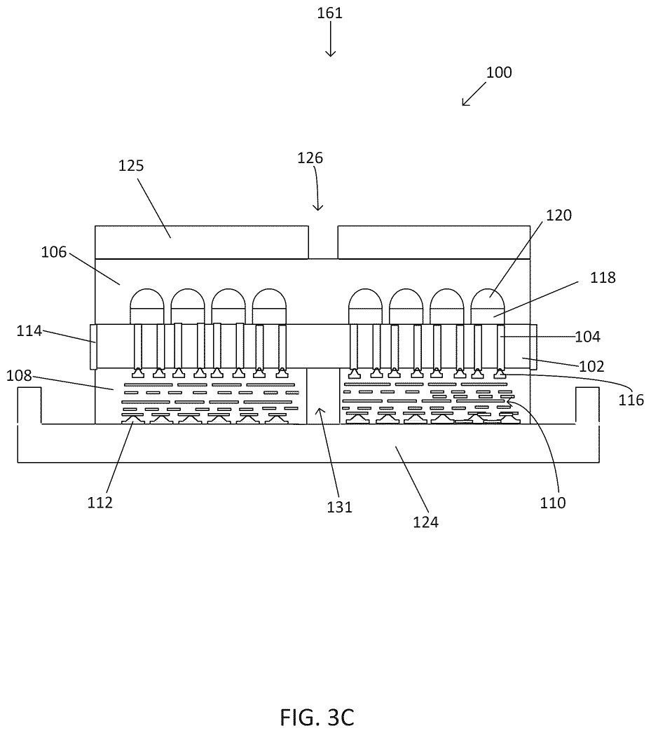

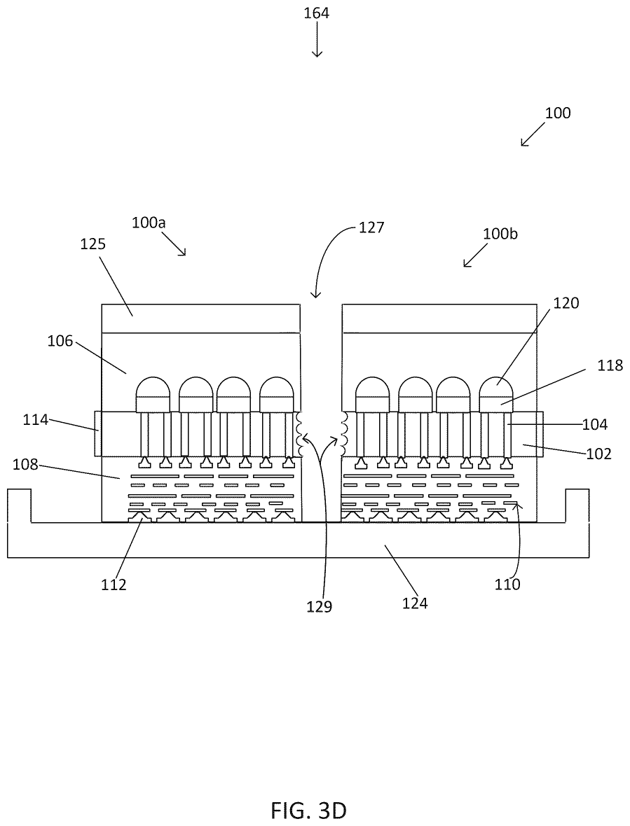

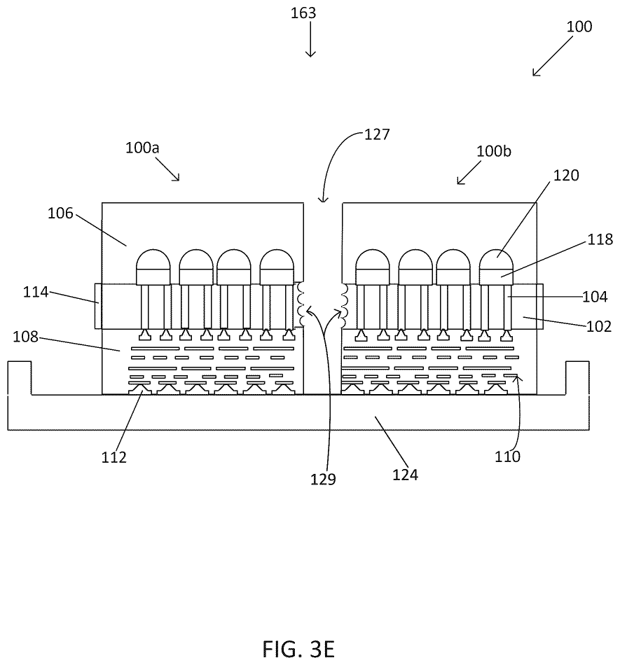

FIGS. 3A-3E depicts a depicts a cross-sectional view of a portion of an EMIB structure 100 prior to a singulation process. EMIB structure 100 comprises two EMIB structures, a first EMIB structure 100a and a second EMIB structure 100b to be singulated from each other in a subsequent dry etching process. In an embodiment, each of the EMIB structures 100a, 100b comprise a silicon material 102 having a first side 141 and a second side 143. In an embodiment, a silicon nitride material 114 is on a sidewall of the silicon material 102.

One or more TSVs 104 may extend from the first side 141 to the second side 143 of the silicon material 102. The one or more TSVs 104 may be filled with a conductive material 124. A non-conductive layer 106 may be on the first side 141 of the silicon material 102. In an embodiment, the non-conductive layer 106 may comprise an adhesive material comprising a resin, a filler, a curing agent and/or a solvent. In an embodiment, a solder cap 120 which may comprise one or more of silicon, gold, or tin, or may comprise any other suitable solder materials may be on a pillar structure 118, which may comprise copper or copper alloys in an embodiment.

A dielectric material 108 may be on the second side 143 of the silicon material 102, with conductive traces 110 distributed throughout the dielectric layer 108 to connect devices, such as IC die or a board, such as a printed circuit (PC) board, for example, with the EMIB structure 100. Conductive TSV contacts 116 within/on a surface of the dielectric material 108 may be electrically and physically coupled with the one or more TSVs 104 within the silicon material 102.

Conductive die contacts 112 may be within/on a surface of the dielectric material 108 and may be on a surface of a carrier structure 124, which may comprise a mylar carrier structure 124 in an embodiment. An opening 131 may be in the dielectric material 108 between the first EMIB structure 100a and the second EMIB structure 100b. In an embodiment, the opening 131 may be formed by performing a lithographic process to define the opening 131 with a photoresist material and then employing a dielectric etching process as is known in the art, during a previous process step.

FIG. 3B depicts a process 160 wherein a coating layer 125 may be formed on a top surface of the non-conductive layer 106. In an embodiment the coating layer 125 may comprise a resist material, and the process 160 may comprise a wafer coating process, wherein the coating layer may be sprayed onto the surface of the non-conductive layer 106. In an embodiment, the non-conductive film 106 may comprise a thickness 132 above the solder cap 120 of about 3 to 5 microns and may be applied to reduce chips and cracks during singulation processes, such as during dicing process, for example. FIG. 3C depicts a patterning process 161 wherein an opening 126 in the resist material 125 may be formed between the first EMIB structure 100a and the second EMIB structure 100b. In an embodiment, the patterning process 161 may comprise a laser patterning process 161. In an embodiment, the laser patterning process 161 may utilize a femto second laser scribe. In an embodiment, the opening 126 in the resist material 125 may be aligned with the opening 131 in the dielectric material 108.

FIG. 3D depicts a removal process 164 wherein a dry etch process is employed to remove the non-conductive layer 106 and the silicon portion 102 between the first EMIB structure 100a and the second EMIB structure 100b. In an embodiment, the removal process 164 may comprise an oxygen plasma etch to remove the non-conductive layer 106 from between the first and second EMIB structures 100a, 100b and a Bosch etch to remove the silicon material 102 between the first and second EMIB structures 100a, 100b. In an embodiment, the dry etch process 164 may form an opening 127 through the non-conductive film 106 and the silicon material 102 to be aligned with the opening 131 within the dielectric material 108. The opening 127 singulates the first EMIB structure 100a from the second EMIB structure 100b.

In an embodiment, scallop structures 129 are formed on an edge/sidewall portion of the silicon material 102. The silicon nitride material 114 is on a sidewall of the silicon material 102, opposite a sidewall of the silicon material 102 comprising the one or more scallops 129. Sidewalls of the non-conductive material 106 and sidewalls of the dielectric material 108 are free of the scallop structures 129. FIG. 3E depicts a process 163, such as an ashing process with a wet cleaning process for example, to remove the photoresist 125 from the surfaces of the first and second EMIB structures 101a, 100b. In an embodiment, the process 163 may comprise a plasma ash and a solvent clean. In an embodiment, the non-conductive layer 106, the silicon material 102 and the dielectric material may be etched to form the opening 127 within one process tool, using up to 3 different chambers.

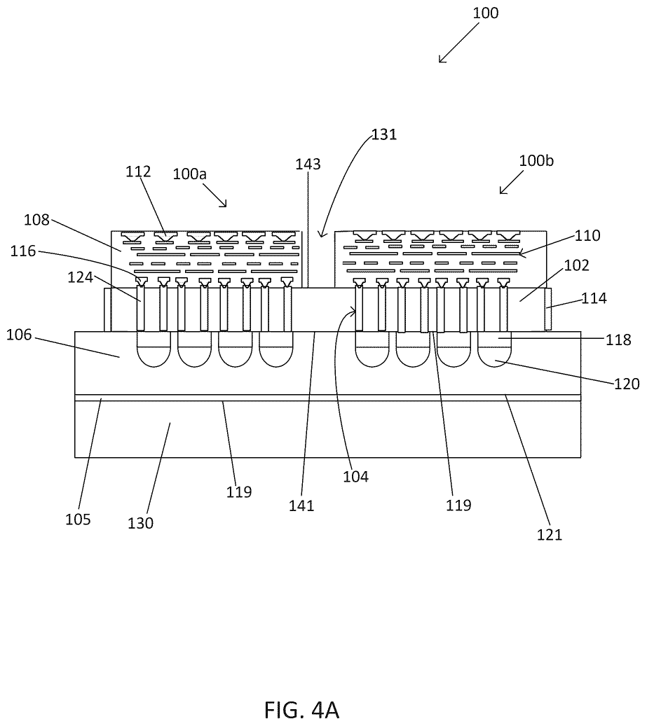

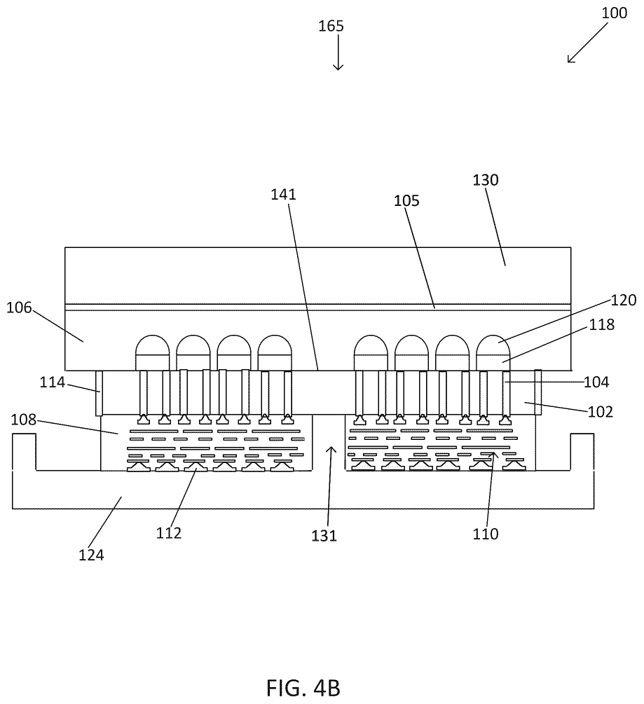

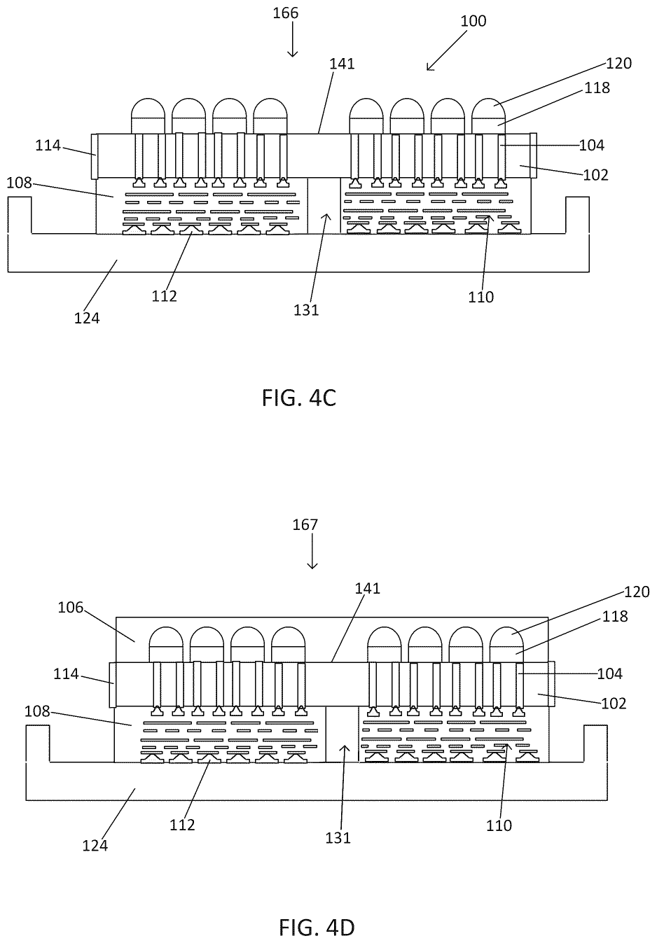

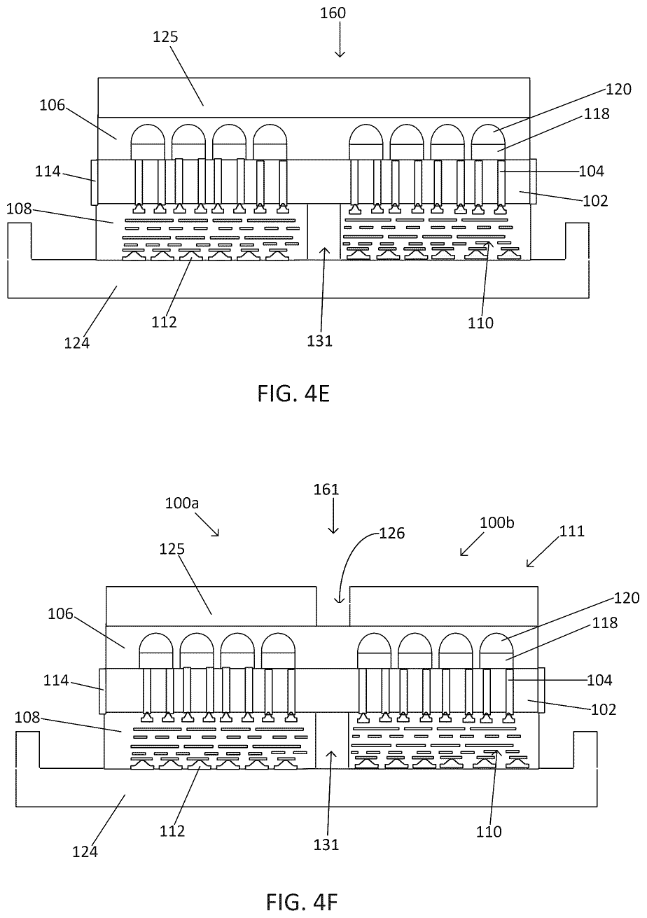

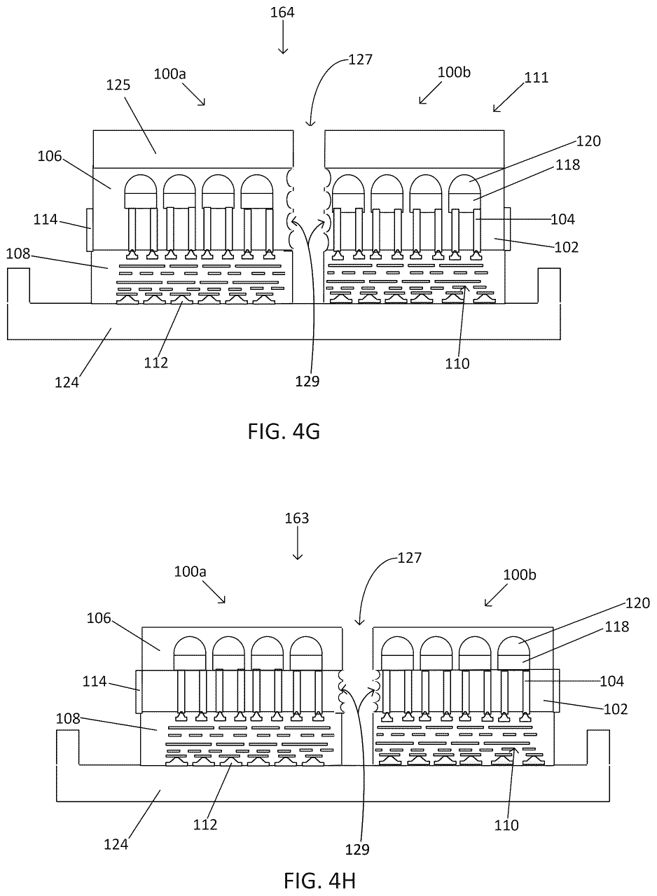

FIGS. 4A-4H depict cross-sectional views of a portion of an EMIB structure 100 prior to a singulation process. FIG. 4A depicts EMIB structure 100 comprising two EMIB structures 100a, 100b to be singulated from each other in a subsequent singulation process. In an embodiment, each of the EMIB structures 100a, 100b comprise a silicon material 102 having a first side 141 and a second side 143. In an embodiment, a silicon nitride material 114 is on a sidewall of the silicon material 102.

One or more TSVs 104 may extend from the first side 141 to the second side 143 of the silicon material 102. The one or more TSVs 104 may be filled with a conductive material 124. A first side 119 of a glass carrier bond layer 105 may be on a glass carrier 130 and a second side 121 of the glass carrier bond layer 105 may be on a non-conductive layer 106. In an embodiment, the carrier wafer 130 may comprise a glass wafer. In an embodiment, the non-conductive layer 106 may surround a solder cap 120 which may comprise one or more of silicon, gold, or tin, or may comprise any other suitable solder materials. The solder cap 120 may be on a pillar structure 118, which may comprise copper or copper alloys in an embodiment.

A dielectric material 108 may be on the second side 143 of the silicon material 102, with conductive traces 110 distributed throughout the dielectric layer 108 to connect devices, such as IC die or a board, such as a printed circuit (PC) board, for example, with the EMIB structure 100. Conductive TSV contacts 116 within/on a surface of the dielectric material 108 may be electrically and physically coupled with the one or more TSVs 104 within the silicon material 102.

Conductive die contacts 112 may be within/on a surface of the dielectric material 108 opposite the second side 143 of the silicon material 102. An opening 131 may be in the dielectric material 108 between the first EMIB structure 100a and the second EMIB structure 100b. The opening 131 may be formed by performing a lithographic process to define the opening 131 with a photoresist material and then employing a dielectric etching process as is known in the art, during a previous process step. In an embodiment, the opening 131 may be formed by using a using laser scribe or saw process.

FIG. 4B depicts a process 165 wherein a surface of the dielectric material 108 of the EMIB structure 100 may be mounted onto a carrier structure 124, which may comprise mylar in an embodiment. FIG. 4C depicts a process 166 wherein the EMIB structure 100 may be de-bonded from the carrier wafer 130, the glass carrier bond layer 105 may be removed, and the EMIB structure 100 may be cleaned. In FIG. 4D, a non-conductive layer 106 may be formed on the first side 141 of the silicon material 102 and around the solder caps 120 by using a lamination process 167.

In FIG. 4E a coating layer 125 may be formed on a top surface of the non-conductive layer 106 by using a coating process 160. FIG. 4F depicts a patterning process 161 wherein an opening 126 in the resist material 125 may be formed between the first EMIB structure 100a and the second EMIB structure 100b. In an embodiment, the patterning process 161 may comprise a laser patterning process 161. In an embodiment, the opening 126 in the resist material 125 may be aligned with the opening 131 in the dielectric material 108.

FIG. 4G depicts a removal process 164 wherein a dry etch process is employed to remove the non-conductive layer 106 and the silicon portion 102 between the first EMIB structure 100a and the second EMIB structure 100b. In an embodiment, the removal process 164 may comprise an oxygen plasma etch to remove the non-conductive layer 106 from between the first and second EMIB structures 100a, 100b and a Bosch etch to remove the silicon material 102 between the first and second EMIB structures 100a, 100b. In an embodiment, the dry etch process 164 may form an opening 127 through the non-conductive film 106 and the silicon material 102 to be aligned with the opening 131 within the dielectric material 108. The opening 127 singulates the first EMIB structure 100a from the second EMIB structure 100b. In an embodiment, scallop structures 129 are formed on an edge/sidewall portion of the silicon material 102, wherein sidewalls of the non-conductive material 106 and sidewalls of the dielectric material 108 are free of the scallop structures 129.

FIG. 4H depicts a process 163, such as an ashing process with a wet cleaning process for example, to remove the photoresist 125 from the surfaces of the first and second EMIB structures 101a, 100b. The present embodiment enables plasma dicing and ashing of the non-conductive layer 106 and the silicon material 102 within one tool, using up to 2 different chambers on a film frame. Since the dielectric material 108 is singulated subsequent to the TSV 104 reveal, the TSV structures 104 are protected from damage during processing.

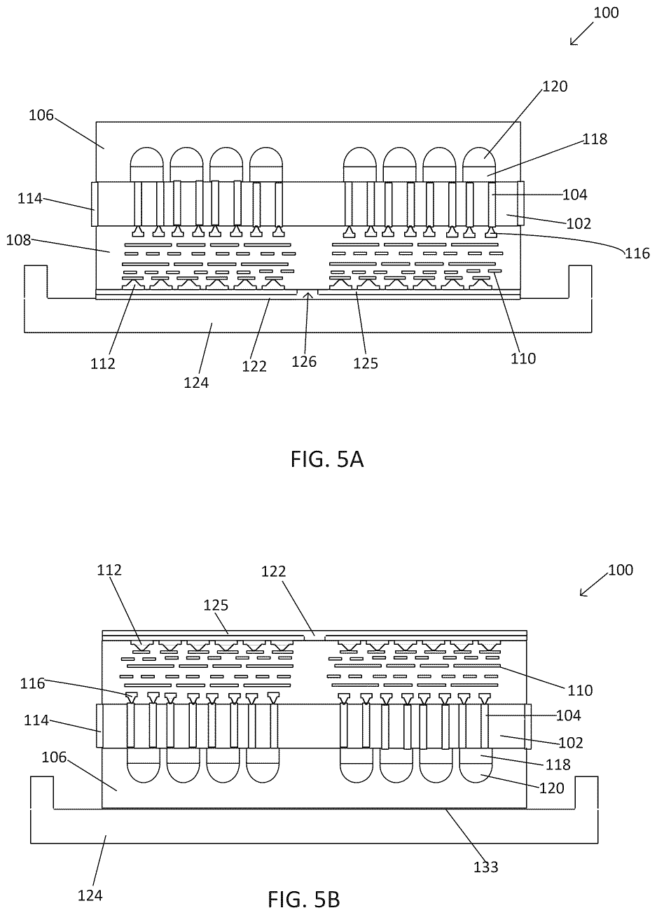

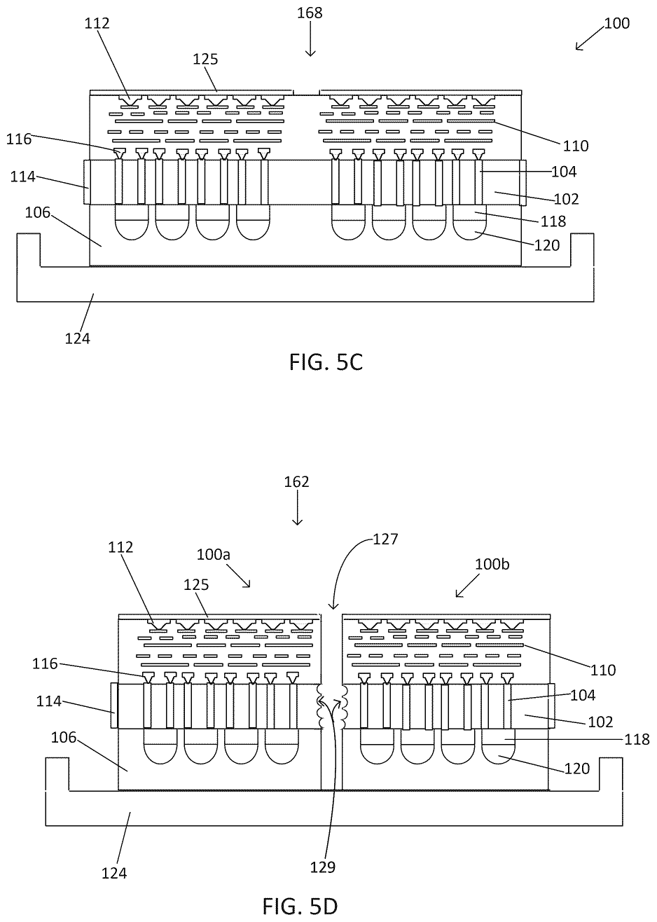

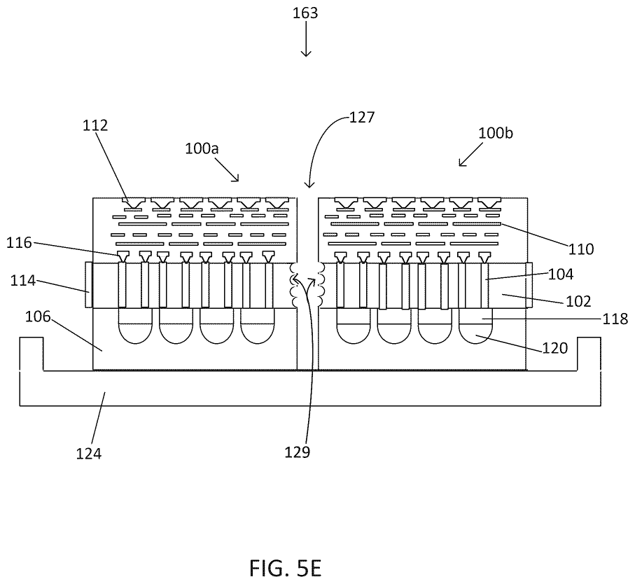

FIGS. 5A-5E depict methods of singulating an EMIB structure 100, similar to the EMIB structure 100 of FIG. 1A, for example. In FIG. 5A, the EMIB structure 100 comprises a photoresist material 125 on a surface of a dielectric material 108. A low temperature dielectric material 122, such as a low temperature silicon dioxide material (SiOx), may be over the photoresist material 125, wherein the low temperature dielectric material 122 is within an opening 126 of the photoresist material 125. The low temperature dielectric material 122 is on a carrier 124. In FIG. 5B the EMIB structure 100 is flipped and a top surface 133 of the non-conductive coating 106 is mounted onto the carrier 124.

In FIG. 5C, the low temperature dielectric material 122 is removed from the resist utilizing removal process, such as a dry etch process 168 and in FIG. 5D, an opening 127 is formed wherein the non-conductive material 106 is removed using a femto second laser scribe for example, followed by a dry etch process to etch the silicon material 102, and then etching the dielectric material 108 to singulate the first EMIB structure 100a from the second EMIB structure 100b. In an embodiment, the dry silicon etch process portion of the multi-step removal process 162 may comprise a silicon dry etch, such as a Botsch etch process, or may comprise any suitable plasma dicing process, for example.

In an embodiment, the removal process 162 may first form an opening 127 through the non-conductive film 106, then through the silicon material 102 and then through the dielectric material 108. The removal process 162 stops on the carrier structure 124. The opening 127 singulates the first EMIB structure 100a from the second EMIB structure 100b. In an embodiment, the silicon etch portion of the removal process 162 forms scallop structures 129 on an edge/sidewall portion of the silicon material 102, wherein the silicon nitride material 114 is on a sidewall of the silicon material 102 that is opposite a sidewall of the silicon material 102 comprising the one or more scallops 129. Sidewalls of the non-conductive material 106 and sidewalls of the dielectric material 108 are free of the scallop structures 129.

FIG. 5E depicts a process 163, such as an ashing process 163 with a wet cleaning process for example, of the first and second EMIB structures 100a, 100b. In an embodiment, the non-conductive layer 106, the silicon material 102 and the dielectric material may be etched to form the opening 127 within one process tool, using up to 3 different chambers.

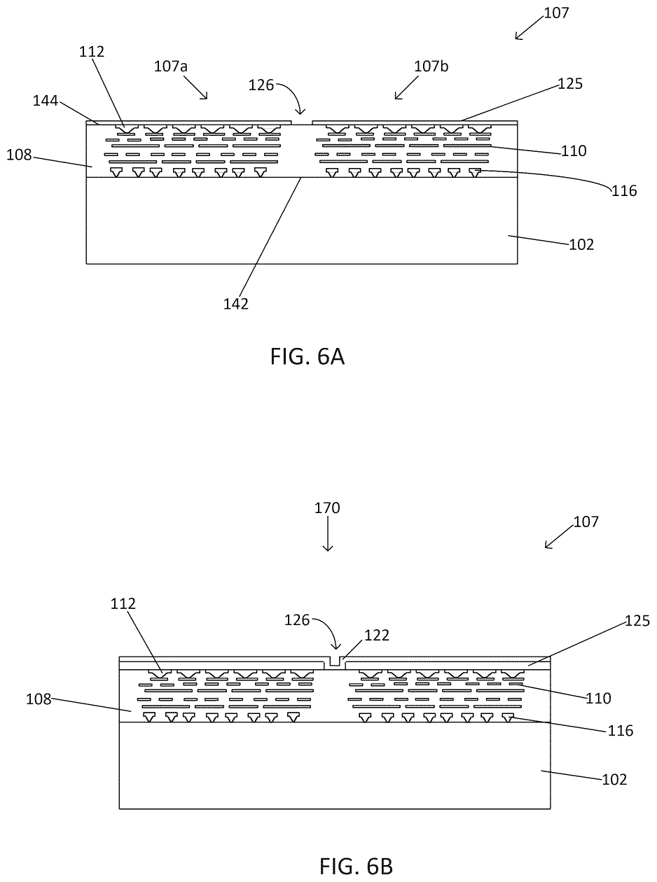

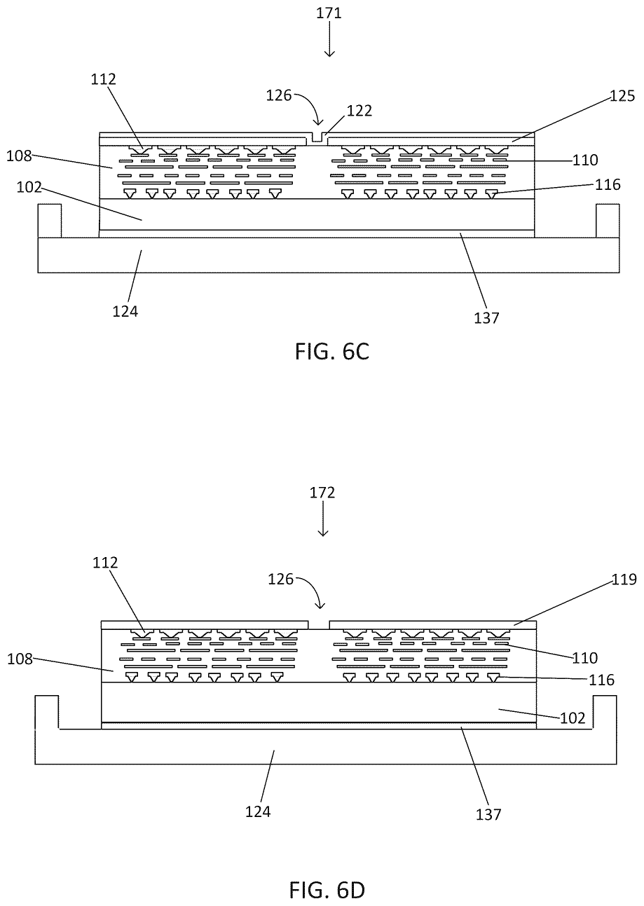

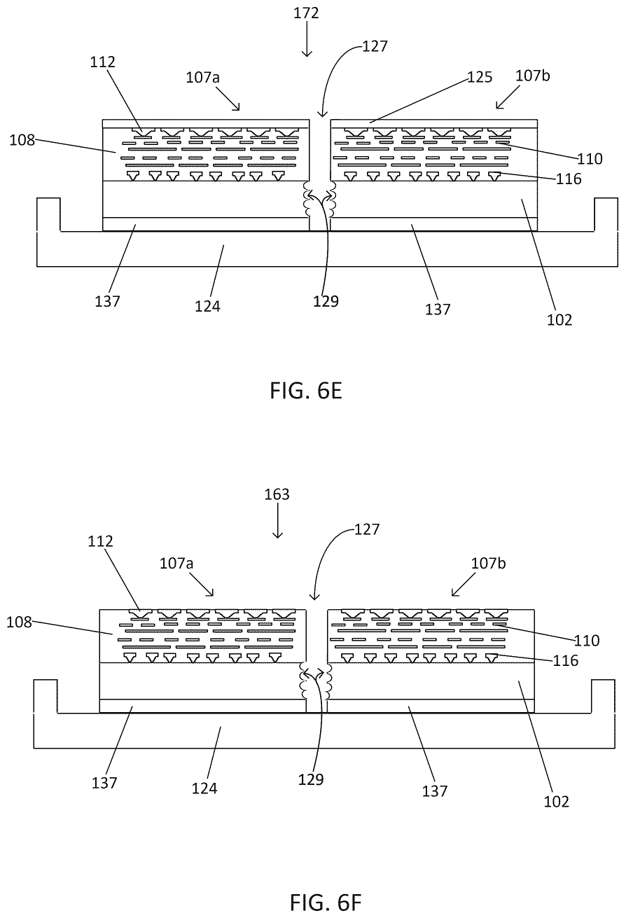

FIGS. 6A-6D depict methods of forming and singulating EMIB structures which do not comprise TSV structures according to embodiments, such as is depicted in FIG. 1D for example. FIG. 6A depicts an EMIB structure 107 comprising two EMIB structures 107a, 107b. In an embodiment, each of the EMIB structures 107a, 107b comprise a silicon material 102 on a first side 142 of a dielectric material 108. A photoresist material 125 is on a second side 144 of the dielectric material 108. Conductive traces 110 may be distributed throughout the dielectric layer 108 to connect devices, such as IC die or a board, such as a printed circuit (PC) board, for example, with the EMIB structure 107. Conductive contacts 116 within/on the first side 142 of the dielectric material 108 may be electrically and physically coupled with the silicon material 102. Conductive die contacts 112 may be on the second side 144 of the dielectric material 108. An opening 126 in the resist material 125 is between a first EMIB structure 107a and a second EMIB structure 107b.

FIG. 6B depicts a formation process 170 wherein a low temperature dielectric material 122, such as a low temperature silicon dioxide material (SiOx), may be formed over the photoresist material 125, wherein the low temperature dielectric material 122 is within the opening 126 of the photoresist material 125. In an embodiment, the low temperature dielectric material 122 may be formed utilizing a plasma deposition process or a chemical deposition process, for example. In an embodiment a thickness of the low temperature dielectric material 122 may comprise between 1 micron to 2 microns.

FIG. 6C depicts wherein the EMIB structure 107 is mounted onto a film 137 such as a die attach film using process 171. The film 137 is on a carrier 124. The silicon material 102 is thinned during a process 171, such as a grinding process. In FIG. 6D the low temperature dielectric material 122 may be removed utilizing a process 172, such as a dielectric etching process for example. In FIG. 6E, a removal process 162 is employed wherein a dry etch process is utilized to etch the dielectric material 108, the silicon material 102 and then the film 137 to singulate the first EMIB structure 107a from the second EMIB structure 107b. In an embodiment, the etch process 162 comprises a plasma etch process, for example. In an embodiment, the removal process 162 may form an opening 127 through the dielectric material 108, the silicon material 102 and the film 137. The removal process 162 stops on the carrier structure 124. An opening 127 singulates the first EMIB structure 107a from the second EMIB structure 107b.

In an embodiment, the silicon etch portion of the removal process 162 forms scallop structures 129 on an edge/sidewall portion of the silicon material 102. The sidewall of the dielectric material 108 is free of the scallop structures 129. A plasma dicing process may be employed in an embodiment. FIG. 6F depicts a process 163, such as an ashing process with a wet cleaning process for example, of the first and second EMIB structures 107a, 107b. In an the dielectric material 108, the silicon material 102 and the film 137 may be etched to form the opening 127 within one process tool, using up to 3 different chambers.

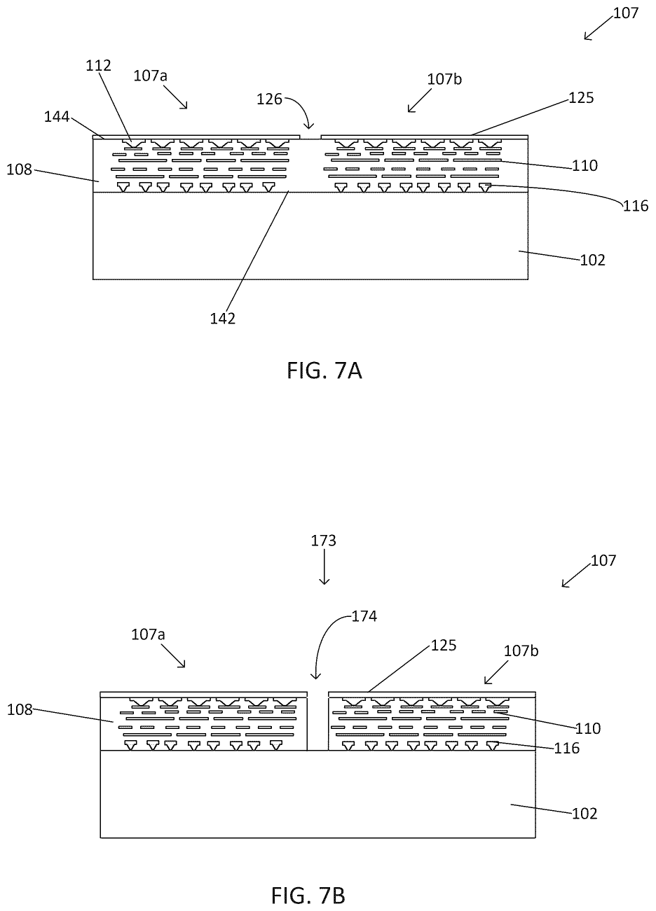

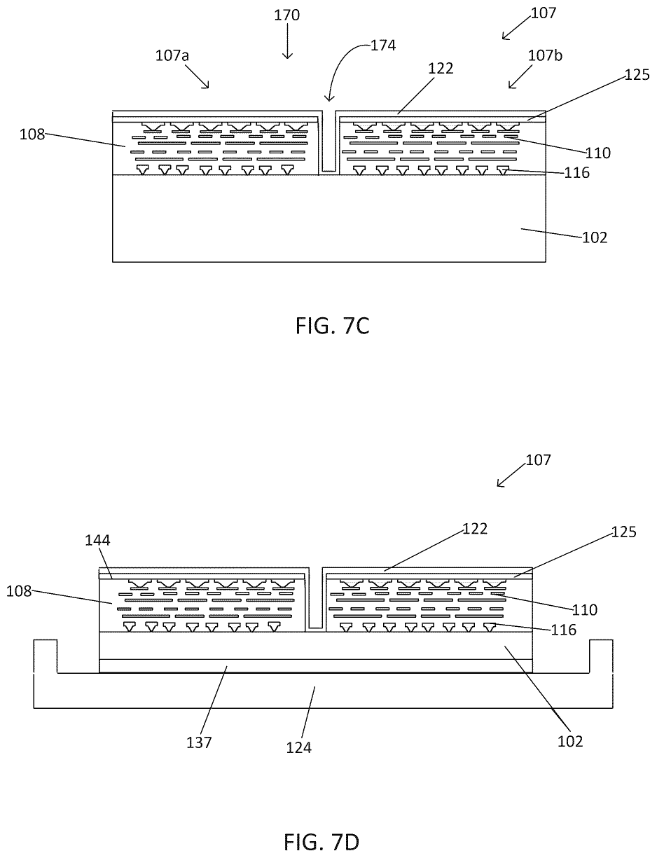

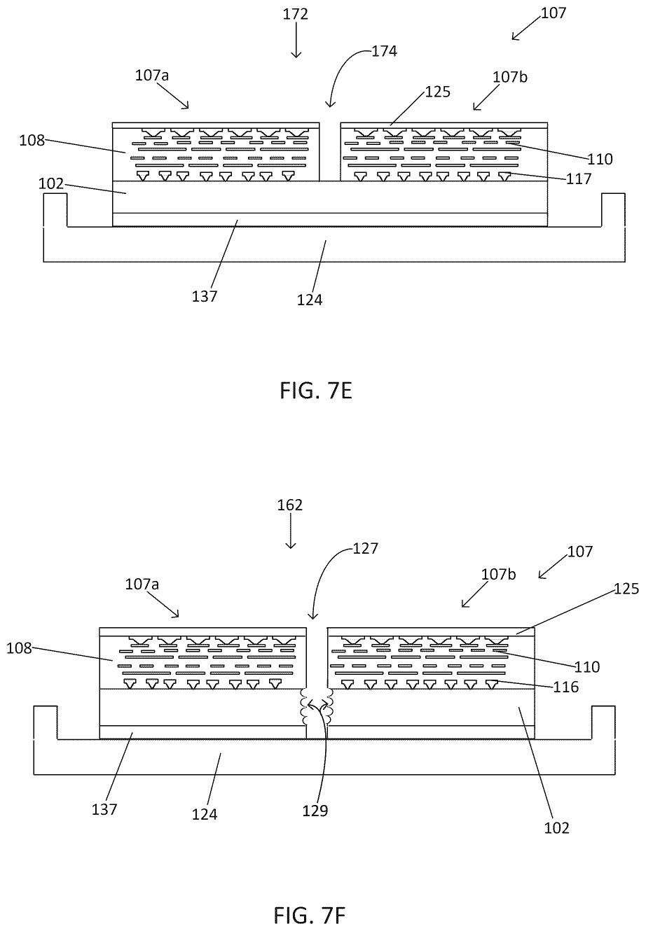

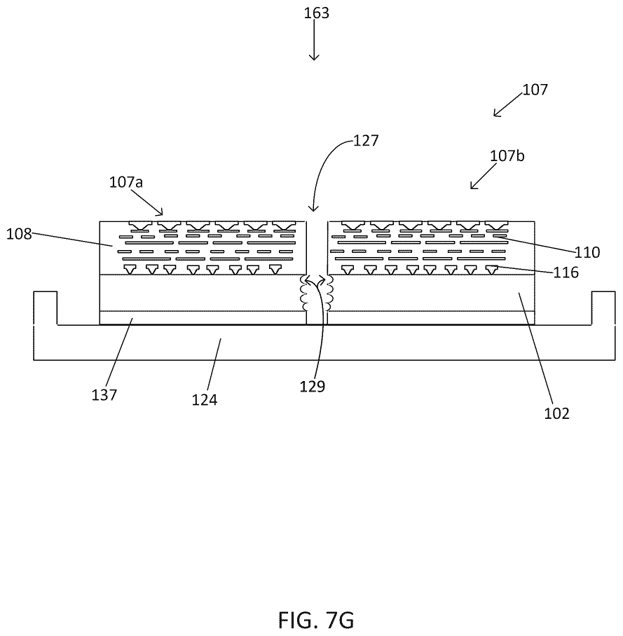

FIGS. 7A-7D depict methods of forming and singulating EMIB structures which do not comprise TSV structures such as is depicted in FIG. 1D, for example, according to embodiments. FIG. 7A depicts an EMIB structure 107 comprising two EMIB structures 107a, 107b. In an embodiment, each of the EMIB structures 107a, 107b comprise a silicon material 102 on a first side 142 of a dielectric material 108. A photoresist material 125 is on a second side 144 of the dielectric material 108. Conductive traces 110 may be distributed throughout the dielectric layer 108 and conductive contacts 116 are within/on the first side 142 of the dielectric material 108 and may be electrically and physically coupled with the silicon material 102. Conductive die contacts 112 may be on the second side 144 of the dielectric material 108. An opening 126 in the resist material 125 is between a first EMIB structure 107a and a second EMIB structure 107b.

FIG. 7B depicts a removal process 173 wherein a dry etch process 173 is utilized to etch the dielectric material 108 between the first EMIB structure 107a from the second EMIB structure 107b to form an opening 174. In an embodiment, the dielectric etch process 173 comprises a plasma etch process, for example. FIG. 7C depicts a formation process 170 wherein a low temperature dielectric material 122, such as a low temperature silicon dioxide material (SiOx), may be formed over the photoresist material 125 and within the opening 174. In an embodiment, the low temperature dielectric material 122 may be formed utilizing a plasma deposition process or a chemical deposition process. FIG. 7D depicts the EMIB structure 107 after it has been mounted onto a carrier 124 and the silicon material 102 has been thinned. The EMIB structure 107 may be in direct contact with a bond layer 137.

In FIG. 7E the low temperature dielectric material 122 may be removed from the opening 174 by utilizing a process 172, such as a dielectric etching process for example. In FIG. 7F, a silicon etch 162 may be utilized to remove the silicon material 102 and the film 137 between the first EMIB structure 107a and the second EMIB structure 107b to singulate the first EMIB structure 107a from the second EMIB structure 107b. In an embodiment, the silicon etch 162 may comprise a Bosch etch, as is known in the art.

In an embodiment, the silicon etch portion of the removal process 162 forms scallop structures 129 on an edge/sidewall portion of the silicon material 102. The sidewall of the dielectric material 108 is free of the scallop structures 129. A plasma dicing process may be employed in an embodiment. FIG. 7G depicts a process 163, such as an ashing process with a wet cleaning process for example, of the first and second EMIB structures 107a, 107b.

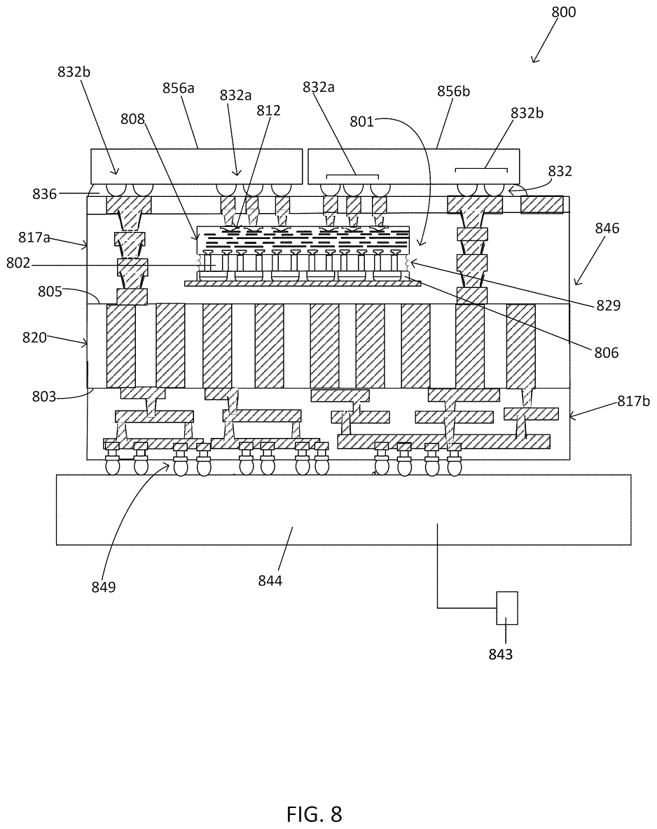

FIG. 8 depicts an IC package structure 800, such as a package structure including an EMIB structure 801. The EMIB structure 801 may be similar to the portions of the package structures depicted in FIGS. 1A-1C for example. The EMIB structure 801 comprises a silicon layer 802 with a dielectric material 808 on one side of the silicon layer 802 and a nonconductive layer 806 on an opposite side of the silicon layer 802. In an embodiment, a first die 856a and a second die 856b may be coupled to the EMIB structure 801. A first set of die contacts 832a may be directly coupled to EMIB die contacts 812, and a second set of die contacts 832b may be coupled to a core 820. The silicon layer 802 of the EMIB structure 801 may comprise two or more scallop structures 829 on a sidewall of the silicon layer 802. In an embodiment, the EMIB structure 801 may be embedded in a first build up layer 817a, wherein buildup layers 817a, 817b are on a first side 805 and a second side 803 of the core 820.

Buildup layers 817a, 817b may comprise a multiple-layer stack of overlaid sheets of laminated film (e.g., buildup film). Buildup layers 817a, 817b materials may include composite epoxies, liquid crystalline polymers and polyimides. Other suitable materials may be employed. In some embodiments, buildup layers 817a, 817b are a monolithic block rather than laminated film. Suitable organic or inorganic materials may be employed. Buildup layers 817a, 817b may include such materials as FR4 (e.g., epoxy-based laminate), bismaleimide-triaxine, polyimide, silicon, or epoxy resin. buildup layers 817a, 817b may comprise organic buildup film or any other dielectric material suitable for electrical packaging.

The buildup layers 817a, 817b may comprise one or more laminated layers in order to form a structure with a desired thickness. In an embodiment, the buildup layers 817a, 817b may comprise electrically conductive features (e.g., pads, traces, vias, etc.) that are fabricated in conjunction with the formation of the buildup layers 817a, 817b. The buildup layers 817a, 817b may include a dielectric material with conductive traces located throughout which may couple another substrate or die. The conductive traces may comprise copper or copper alloys in an embodiment.

The core 820 may comprise any suitable materials such as glass or dielectric materials in an embodiment. In an embodiment, the dies 856a, 856b may comprise chiplet structures which may comprise components of a system on a chip (SOC) structure. Any number of die/devices may be coupled to the EMIB structure 801. A package substrate 846 (comprising the core 820 and build up layers 817a, 817b) and device(s) 856a, 856b may be coupled to a board 844, such as a printed circuit board, in an embodiment. The board 844 may be coupled to the package substrate 846 through solder structures 849 in an embodiment. A power supply 843, which may comprise any suitable power supply as known in the art, may be coupled to dies 856a, 856b via IC package substrate 846, in an embodiment. Solder interconnect structures 832 may couple the die 856a, 856b to the substrate 846. An underfill material 836 may surround the solder structures 832, in an embodiment.

Discussion now turns to operations for assembling and/or fabricating the discussed structures.

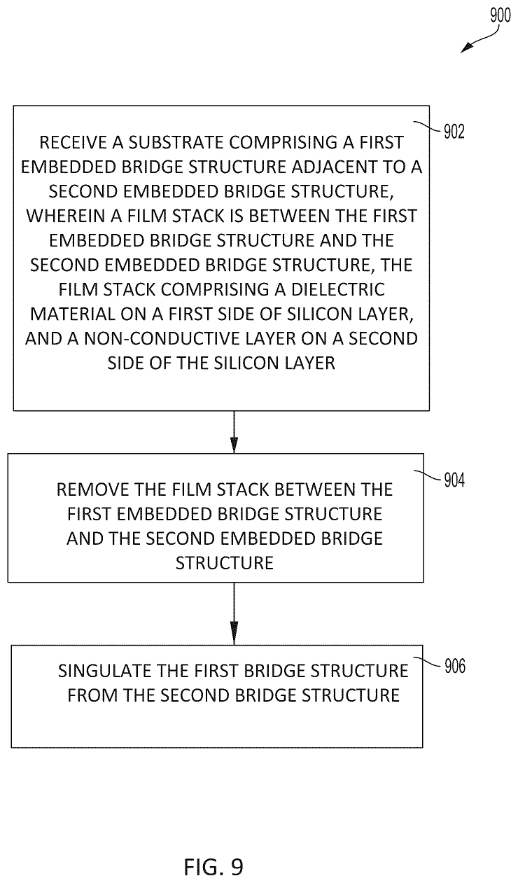

FIG. 9 is a flow chart of a process 900 of fabricating package structures, such as a package substrate comprising an EMIB structure coupled to two or more die, wherein the EMIB structure comprises a silicon sidewall with two or more scallop structures. For example, process 900 may be used to fabricate any of the microelectronic IC package structures of FIGS. 1A-1D, for example.

As set forth in block 902, a substrate may be received comprising a first embedded interconnect bridge interconnect structure adjacent to a second embedded interconnect bridge structure, wherein the substrate may be on a carrier. Each bridge structure may comprise a silicon layer with a non-conductive layer on a first side of the silicon layer and a dielectric layer on a second side of the silicon layer, opposite the first side. The non-conductive layer may comprise a resin and a filler material and may comprise an organic material in an embodiment. The non-conductive layer may comprise a thickness of between 1 micron and 5 microns in an embodiment.

In an embodiment, copper pillar structures may be on each of a plurality of conductive TSV structures which extend from the first side of the silicon layer to the second side of the silicon layer, wherein the non-conductive layer surrounds the copper pillars. In an embodiment, the metal vias may comprise through glass vias in an embodiment, wherein the conductive material may comprise copper or a copper alloy materials in an embodiment. Solder structures are on the copper pillar structures, wherein the non-conductive layer extends 1-3 microns above the solder structures. In other embodiments, the silicon layer is free of TSV structures. A silicon nitride material is on a silicon layer sidewall. A thickness of the silicon nitride layer is between 1-2 microns.

A film stack is between the first embedded bridge structure and the second embedded bridge structure, the film stack comprising the dielectric material on the first side of the silicon layer, and the non-conductive layer on the second side of the silicon layer. of glass. As set forth in step 904, the film stack may be removed between the first embedded bridge structure and the second embedded bridge structure. In an embodiment, the dielectric material may be removed with a dielectric plasma etch. In an embodiment, the non-conductive material and the dielectric material may be removed/etched in the same etch step within the same or a different etch tool using different chambers.

In an embodiment, the silicon layer may be removed from between the EMIB structures utilizing a silicon etch, such as a Bosch etch for example, wherein a plurality of scallop structures are formed along a sidewall of the silicon layer between the first and second EMIB structures. Two or more scallop structures are formed along the silicon sidewall. In an embodiment, the silicon nitride layer is on a sidewall opposite the sidewall comprising the scallop structures. In an embodiment, the dielectric sidewalls and nonconductive layer sidewalls are free of the scallop structures.

As set forth in block 906, the first bridge structure may be singulated from the second bridge structure and may be removed from the carrier. The singulated bridge structures may be incorporated into a package substrate to couple a first die with a second die, as depicted in FIG. 8 for example. One or more die may be attached on build-up layers of a core. The die may comprise a central processing unit (CPU) or a field programmable gate array (FPGA) die, for example or may comprise any suitable logic die for the particular application. The die may be attached utilizing any suitable die attach process, as are known in the art.

The embodiments disclosed herein may be incorporated with any bridge die size (e.g. 0.5 mm×0.5mm) and or aspect ratios (such as 3 mm×36mm), and does not require subsequent stretch processes whose yield is dependent on die size and aspect ratios. The embodiments herein enable singulation of dielectric, silicon, and non-conductive material in a multi-step fashion.

The embodiments herein eliminate front side chipping and back side chipping associated with blade saw based thin die dicing and enable high die yield strength leading to much better yields at substrate assembly processes.

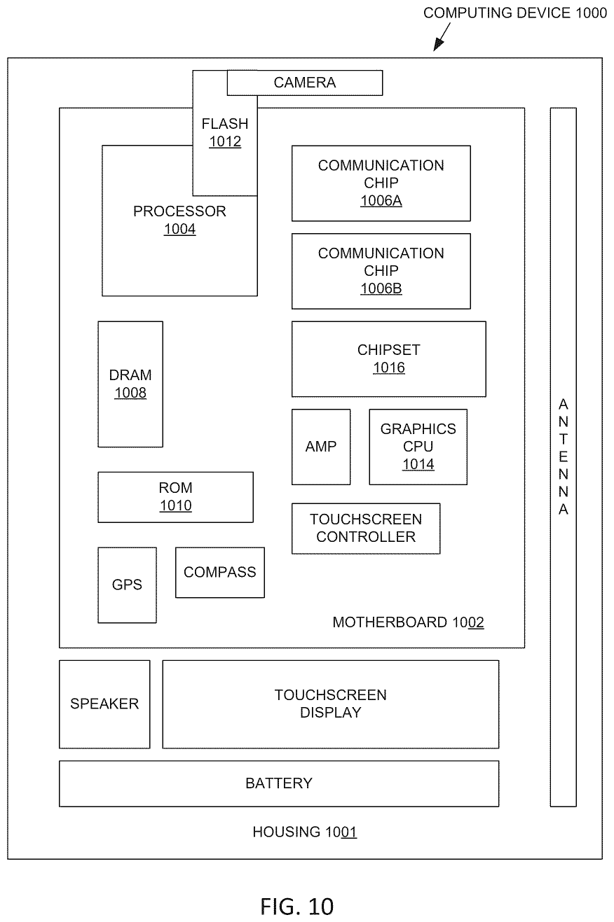

FIG. 10 illustrates an electronic or computing device 1000 in accordance with one or more implementations of the present description. The computing device 1000 may include a housing 1001 having a board 1002 disposed therein. The computing device 1000 may include a number of integrated circuit components, including but not limited to a processor 1004, at least one communication chip 1006A, 1006B, volatile memory 1008 (e.g., DRAM), non-volatile memory 1010 (e.g., ROM), flash memory 1012, a graphics processor or CPU 1014, a digital signal processor (not shown), a crypto processor (not shown), a chipset 1016, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the integrated circuit components may be physically and electrically coupled to the board 1002. In some implementations, at least one of the integrated circuit components may be a part of the processor 1004.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory. At least one of the integrated circuit components may include an EMIB structure embedded within a package structure comprising a silicon sidewall with two or more scallops coupled to two or more dies.

In various implementations, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure. It is understood that the subject matter of the present description is not necessarily limited to specific applications illustrated in FIGS. 1-10. The subject matter may be applied to other integrated circuit devices and assembly applications, as well as any appropriate electronic application, as will be understood to those skilled in the art.

The following examples pertain to further embodiments and specifics wherein the examples may be used anywhere in one or more embodiments, wherein a first example is an apparatus comprising a bridge structure within a substrate, the bridge structure comprising a plurality of vias extending through a silicon layer, wherein a sidewall of the silicon layer comprises two or more scallop structures. A non-conductive layer on a first side of the silicon layer, wherein one or more conductive bumps are embedded within the non-conductive layer, A dielectric layer on a second side of the silicon layer; and a plurality of die contacts at least partially on a surface of the dielectric layer; a first die over the bridge structure, the first die coupled to the plurality of die contacts; and a second die over the bridge structure, adjacent to the first die, the second die coupled to the plurality of die contacts.

In second examples, wherein the first example further comprises wherein the non-conductive layer comprises a resin and a filler, and wherein the dielectric layer comprises an organic laminate material.

In third examples, wherein any of examples 1-2 further comprises wherein a sidewall of the dielectric layer is free of the two or more scallop structures.

In fourth examples, wherein any of examples 1-3 further comprise wherein the plurality of vias comprise a conductive material.

In fifth examples, wherein any of examples 1-4 further comprises wherein the conductive material comprises copper or copper alloys, and wherein the plurality of vias comprise a plurality of through silicon vias (TGVs).

In sixth examples, wherein any of examples 1-5 further comprises wherein at least one of the first die or the second die comprise one or more of a logic die, a central processing die, a memory die, a WiFi transmitter die, or a global positioning system die and wherein the one or more conductive bumps comprise gold, tin or silicon.

In seventh examples, wherein any of examples 1-6 further comprises wherein the one or more conductive bumps are coupled to the plurality of vias, and wherein the non-conductive layer extends 1 micron to 3 microns above the one or more conductive bumps.

In eighth examples, wherein any of examples 1-7 further comprises wherein the first die comprises a first set of die contact structures and a second set of die contact structures, adjacent to the first set of die contact structures, wherein the first set of die contact structures is coupled to the bridge structure, and the second set of die contact structures are coupled to a core.

In ninth examples, wherein any of examples 1-8 further comprises a plurality of conductive traces embedded in the dielectric layer.

In tenth examples, wherein any of examples 1-8 further comprises wherein the plurality of vias comprise a pitch between individual adjacent vias of between 5 microns and 10 microns.

In eleventh examples, wherein any of examples 1-10 further comprises wherein the sidewall comprises a first sidewall, and a second sidewall, opposite the first sidewall comprises a silicon nitride layer.

Example 12 is an apparatus comprising a bridge structure within a substrate, the bridge structure comprising; a silicon layer comprising a sidewall, wherein a sidewall of the silicon layer comprises two or more semicircular indentations; a non-conductive film on a first side of the silicon layer; and a dielectric layer on a second side of the silicon layer, wherein a plurality of bridge contacts are at least partially on a surface of the dielectric layer; a first die over the bridge structure, the first die coupled to the plurality of bridge contacts; and a second die over the bridge structure, adjacent to the first die, the second die coupled to the plurality of bridge contacts.

In thirteenth examples, wherein examples 12 further comprises wherein the sidewall of the silicon layer comprises a first sidewall, and wherein a second sidewall of the silicon layer comprises a second sidewall, opposite the first sidewall, wherein the second sidewall is free of the two or more semicircular indentations.

In fourteenth examples, wherein any of examples 12-13 further comprise wherein the second sidewall comprises a silicon nitride layer.

In fifteenth examples, wherein any of examples 12-14 further comprise wherein the first die comprises a set of core contacts adjacent to the bridge contacts, wherein individual ones of the core contacts comprise a lateral width that is greater than a lateral width of individual ones of the bridge contacts.

In sixteenth examples, wherein any of examples 12-15 further comprises further comprising a plurality of conductive vias extending through the silicon layer.

Example 17 is a method comprising receiving a substrate comprising a first embedded bridge structure adjacent to a second embedded bridge structure, wherein a film stack is between the first embedded bridge structure and the second embedded bridge structure, the film stack comprising a dielectric material on a first side of silicon layer, and a non-conductive layer on a second side of the silicon layer; removing the film stack between the first embedded bridge structure and the second embedded bridge structure; and singulating the first embedded bridge structure from the second embedded bridge structure.

In eighteenth examples, wherein example 17 further comprises wherein removing the film stack comprises using a plasma etching process to remove the film stack.

In nineteenth examples, wherein example 18 further comprises wherein the plasma etching process comprises a Bosch etching process, wherein a sidewall of the silicon layer comprises two or more scallop structures.

In twentieth examples, wherein any of example 17-18 further comprises wherein the first embedded bridge structure comprises a plurality of vias extending through the silicon layer.

It will be recognized that principles of the disclosure are not limited to the embodiments so described but can be practiced with modification and alteration without departing from the scope of the appended claims. The above embodiments may include the undertaking only a subset of such features, undertaking a different order of such features, undertaking a different combination of such features, and/or undertaking additional features than those features explicitly listed. The scope of the embodiments should, therefore, be determined with reference to the appended claims, along with the full scope of equivalents to which such claims are entitled.

What is claimed is:

1. An apparatus, comprising:
a bridge structure within a substrate, the bridge structure comprising:
a plurality of vias extending through a silicon layer, wherein a sidewall of the silicon layer comprises two or more scallop structures;
a non-conductive layer on a first side of the silicon layer, wherein one or more conductive bumps are embedded within the non-conductive layer;
a dielectric layer on a second side of the silicon layer; and
a plurality of die contacts at least partially on a surface of the dielectric layer;
a first die over the bridge structure, the first die coupled to the plurality of die contacts; and
a second die over the bridge structure, adjacent to the first die, the second die coupled to the plurality of die contacts.

2. The apparatus of claim 1, wherein the non-conductive layer comprises a resin and a filler, and wherein the dielectric layer comprises an organic laminate material.

3. The apparatus of claim 2, wherein a sidewall of the dielectric layer is free of the two or more scallop structures.

4. The apparatus of claim 1, wherein the plurality of vias comprise a conductive material.

5. The apparatus of claim 4, wherein the conductive material comprises copper or copper alloys, and wherein the plurality of vias comprise a plurality of through silicon vias (TGVs).

6. The apparatus of claim 1, wherein at least one of the first die or the second die comprise one or more of a logic die, a central processing die, a memory die, a WiFi transmitter die, or a global positioning system die and wherein the one or more conductive bumps comprise gold, tin or silicon.

7. The apparatus of claim 1, wherein the one or more conductive bumps are coupled to the plurality of vias, and wherein the non-conductive layer extends 1 micron to 3 microns above the one or more conductive bumps.

8. The apparatus of claim 1, wherein the first die comprises a first set of die contact structures and a second set of die contact structures, adjacent to the first set of die contact structures, wherein the first set of die contact structures is coupled to the bridge structure, and the second set of die contact structures are coupled to a core.

9. The apparatus of claim 1, further comprising a plurality of conductive traces embedded in the dielectric layer.

10. The apparatus of claim 1, wherein the plurality of vias comprise a pitch between individual adjacent vias of between 5 microns and 10 microns.

11. The apparatus of claim 1, wherein the sidewall comprises a first sidewall, and a second sidewall, opposite the first sidewall comprises a silicon nitride layer.

12. An apparatus, comprising:
a bridge structure within a substrate, the bridge structure comprising;
a silicon layer comprising a sidewall, wherein a sidewall of the silicon layer comprises two or more semicircular indentations;
a non-conductive film on a first side of the silicon layer; and
a dielectric layer on a second side of the silicon layer, wherein a plurality of bridge contacts are at least partially on a surface of the dielectric layer;
a first die over the bridge structure, the first die coupled to the plurality of bridge contacts; and
a second die over the bridge structure, adjacent to the first die, the second die coupled to the plurality of bridge contacts.

13. The apparatus of claim 12, wherein the sidewall of the silicon layer comprises a first sidewall, and wherein a second sidewall of the silicon layer comprises a second sidewall, opposite the first sidewall, wherein the second sidewall is free of the two or more semicircular indentations.

14. The apparatus of claim 13, wherein the second sidewall comprises a silicon nitride layer.

15. The apparatus of claim 12, wherein the first die comprises a set of core contacts adjacent to the bridge contacts, wherein individual ones of the core contacts comprise a lateral width that is greater than a lateral width of individual ones of the bridge contacts.

16. The apparatus of claim 12, further comprising a plurality of conductive vias extending through the silicon layer.

17. A method, comprising:
receiving a substrate comprising a first embedded bridge structure adjacent to a second embedded bridge structure, wherein a film stack is between the first embedded bridge structure and the second embedded bridge structure, the film stack comprising a dielectric material on a first side of silicon layer, and a non-conductive layer on a second side of the silicon layer;
removing the film stack between the first embedded bridge structure and the second embedded bridge structure; and
singulating the first embedded bridge structure from the second embedded bridge structure.

18. The method of claim 17, wherein removing the film stack comprises using a plasma etching process to remove the film stack.

19. The method of claim 18, wherein the plasma etching process comprises a Bosch etching process, wherein a sidewall of the silicon layer comprises two or more scallop structures.

20. The method of claim 17, wherein the first embedded bridge structure comprises a plurality of vias extending through the silicon layer.
